(19) United States
(12) Patent Application Publication
(10) Pub. No.: US 2026/0096299 A1
(43) Pub. Date: Apr. 2, 2026

(54) DISPLAY DEVICE

(71) Applicant: Magnolia White Corporation, Tokyo (JP)

(72) Inventors: Sho YANAGISAWA, Tokyo (JP); Tomokazu ISHIKAWA, Tokyo (JP); Hideyuki TAKAHASHI, Tokyo (JP)

(73) Assignee: Magnolia White Corporation, Tokyo (JP)

(21) Appl. No.: 19/340,963

(22) Filed: Sep. 26, 2025

(30) Foreign Application Priority Data
Oct. 2, 2024 (JP) 2024-173312

(51) Int. Cl. H10K 59/122; H10K 59/80

(52) U.S. Cl. CPC H10K 59/122; H10K 59/873

(57) ABSTRACT

According to one embodiment, a display device includes an organic insulating layer provided across a display area and a surrounding area, an inorganic insulating layer covering the organic insulating layer, a lower electrode provided on the organic insulating layer in the display area, an organic layer provided on the lower electrode, an upper electrode provided on the organic layer, a partition formed in an overhang shape, a stacked film provided in the surrounding area, a first sealing layer formed of an inorganic insulating material and provided on the stacked layer, and a first resin layer provided above the first sealing layer. A first edge portion of the first resin layer is located directly above the first sealing layer.

### CROSS-REFERENCE TO RELATED APPLICATIONS

This application is based upon and claims the benefit of priority from Japanese Patent Application No. 2024-173312, filed Oct. 2, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique for suppressing decreases in reliability is required.

### BRIEF DESCRIPTION OF THE DRAWINGS

FIG. 1 is a view showing a configuration example of a display device DSP.

FIG. 2 is a diagram showing an example of the layout of the subpixels SP1, SP2, and SP3 which constitute one pixel PX.

FIG. 3 is a schematic cross-sectional view of the display device DSP along the A-B line of FIG. 2.

FIG. 4A is a schematic plan view of the display device DSP for describing a configuration example of a surrounding area SA.

FIG. 4B is a schematic plan view of the display device DSP for describing another configuration example of the surrounding area SA.

FIG. 5A is a schematic cross-sectional view of the display device DSP along the C-D line of the surrounding area SA shown in FIG. 4A.

FIG. 5B is a cross-sectional view showing the vicinity of edge portions E1 and E2 shown in FIG. 5A in an enlarged manner.

FIG. 5C is a view for describing an influence of moisture penetration in the vicinity of the edge portion E2.

FIG. 6A is a view for describing a manufacturing method of the display device DSP.

FIG. 6B is a view for describing the manufacturing method of the display device DSP.

FIG. 6C is a view for describing the manufacturing method of the display device DSP.

FIG. 6D is a view for describing the manufacturing method of the display device DSP.

FIG. 6E is a view for describing the manufacturing method of the display device DSP.

FIG. 6F is a view for describing the manufacturing method of the display device DSP.

FIG. 6G is a view for describing the manufacturing method of the display device DSP.

FIG. 6H is a view for describing the manufacturing method of the display device DSP.

FIG. 6I is a view for describing the manufacturing method of the display device DSP.

FIG. 7A is a cross-sectional view showing another configuration example of the display device DSP along the C-D line of the surrounding area SA shown in FIG. 4A.

FIG. 7B is a cross-sectional view showing the vicinity of an edge portion E3 shown in FIG. 7A in an enlarged manner.

FIG. 8 is a cross-sectional view showing another configuration example of the display device DSP along the C-D line of the surrounding area SA shown in FIG. 4A.

FIG. 9 is a cross-sectional view showing another configuration example of the display device DSP along the C-D line of the surrounding area SA shown in FIG. 4A.

FIG. 10A is a cross-sectional view showing another configuration example of the display device DSP along the C-D line of the surrounding area SA shown in FIG. 4A.

FIG. 10B is a cross-sectional view showing the vicinity of the edge portions E1 and E2 shown in FIG. 10A in an enlarged manner.

FIG. 11A is a cross-sectional view showing another configuration example of the display device DSP along the C-D line of the surrounding area SA shown in FIG. 4A.

FIG. 11B is a cross-sectional view showing the vicinity of the edge portions E1 and E2 shown in FIG. 11A in an enlarged manner.

FIG. 12A is a cross-sectional view showing another configuration example of the display device DSP along the C-D line of the surrounding area SA shown in FIG. 4A.

FIG. 12B is a cross-sectional view showing the vicinity of the edge portions E1 and E2 shown in

FIG. 12A in an enlarged manner.

### DETAILED DESCRIPTION

An object of embodiments is to provide a display device capable of suppressing decreases in reliability.

In general, according to one embodiment, a display device includes a substrate, an organic insulating layer provided across a display area for displaying images and a surrounding area outside the display area above the substrate, an inorganic insulating layer provided across the display area and the surrounding area and covering the organic insulating layer, a lower electrode provided on the organic insulating layer in the display area and having a peripheral portion covered with the inorganic insulating layer, an organic layer provided on the lower electrode and including a light emitting layer, an upper electrode provided on the organic layer, a partition formed in an overhang shape and including a first lower portion provided on the inorganic insulating layer, having conductivity, and contacting the upper electrode and a first upper portion provided on the first lower portion, a stacked film provided in the surrounding area and including a thin layer formed of same material as each of the organic layer and the upper electrode, a first sealing layer formed of an inorganic insulating material and provided on the stacked film, and a first resin layer provided above the first sealing layer. A first edge portion of the first resin layer is located directly above the first sealing layer.

According to another embodiment, a display device includes a substrate, an organic insulating layer provided across a display area for displaying images and a surrounding area outside the display area above the substrate, an inorganic insulating layer provided across the display area and the surrounding area and covering the organic insulating layer, a lower electrode provided on the organic insulating layer in the display area and having a peripheral portion covered with the inorganic insulating layer, an organic layer provided on the lower electrode and including a light emitting layer, an upper electrode provided on the organic layer, a partition formed in an overhang shape and including a first lower portion provided on the inorganic insulating layer, having conductivity, and contacting the upper electrode and a first upper portion provided on the first lower portion, a stacked film provided in the surrounding area and including a thin layer formed of same material as each of the organic layer and the upper electrode, a first sealing layer formed of an inorganic insulating material and provided on the stacked film, a first resin layer provided above the first sealing layer, a second sealing layer covering the first resin layer, and a second resin layer provided on the second sealing layer. A third edge portion of the second resin layer is located directly above the first sealing layer.

The present embodiment can provide a display device capable of suppressing decreases in reliability.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

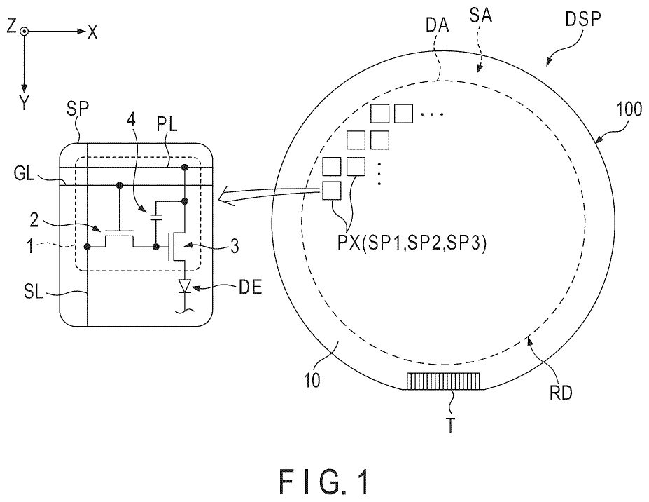

FIG. 1 is a view showing a configuration example of a display device DSP.

The display device DSP comprises a display panel 100. The display panel 100 has a display area DA for displaying an image and a surrounding area SA around the display area DA on an insulating substrate 10. The substrate 10 may be either a glass substrate or a resinous substrate having flexibility.

The outer edge of at least a part of the display area DA has a round portion RD. In the illustrated example, the display area DA has a circular shape in plan view. The shape of the display area DA in plan view is not limited to the illustrated example. For example, the outer edge of the display area DA may be constituted by the round portion RD and a straight portion.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The round portion RD in the display area DA is a shape in a macroscopic scale. In a microscopic scale, this shape is formed by providing a plurality of pixels PX in a stair step layout.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to the display element DE. In the illustrated example, the scanning line GL and the power line PL extend in the first direction X and the signal line SL extends in the second direction Y.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display elements DE.

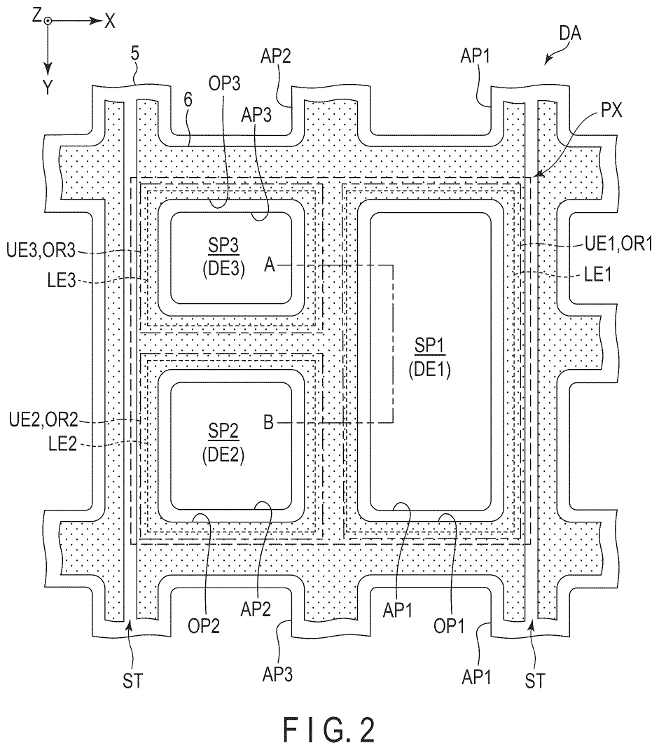

FIG. 2 is a diagram showing an example of the layout of the subpixels SP1, SP2, and SP3 which constitute one pixel PX.

In the illustrated example, the subpixels SP2 and SP3 are arranged in the second direction Y. The subpixels SP1 and SP2 are arranged in the first direction X. The subpixels SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the illustrated example.

An inorganic insulating layer 5 and a partition 6 are provided in the display area DA. The inorganic insulating layer 5 has apertures AP1, AP2, and AP3 in the respective subpixels SP1, SP2, and SP3. The inorganic insulating layer 5 having these apertures AP1, AP2, and AP3 may be called a rib.

The partition 6 overlaps the inorganic insulating layer 5 in plan view. The partition 6 is formed into a grating shape surrounding the apertures AP1, AP2, and AP3. That is, the partition 6 has respective apertures OP1, OP2, and OP3 in the respective subpixels SP1, SP2, and SP3 in the same manner as the inorganic insulating layer 5. The aperture OP1 overlaps the aperture AP1. The aperture OP2 overlaps the aperture AP2. The aperture OP3 overlaps the aperture AP3. The partition 6 is conductive and is electrically connected to a terminal with common voltage at the terminal portion T shown in FIG. 1.

The subpixels SP1, SP2, and SP3 comprise respective display elements DE1, DE2, and DE3 as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered with the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered with the inorganic insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the inorganic insulating layer 5 in plan view.

In the illustrated example, the outlines of the lower electrodes LE1, LE2, and LE3 are indicated by dotted lines, and the outlines of the organic layers OR1, OR2, and OR3 and the upper electrodes UE1, UE2, and UE3 are indicated by one-dot chain line. The outlines of the respective lower electrode, organic layer, and upper electrode shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planar size of the aperture AP1, the planar size of the aperture AP2, and the planar size of the aperture AP3 differ from each other. The planar size of the aperture AP1 is greater than the aperture AP2. The planar size of the aperture AP2 is greater than the aperture AP3. The magnitude relationship of the planar sizes of the apertures AP1, AP2, and AP3 is not limited to the illustrated example.

The partition 6 has a plurality of slits ST. In the illustrated example, each of the slits ST extends in the second direction Y. For example, the subpixels SP1, SP2, and SP3 constituting one pixel PX are provided between two slits ST adjacent to each other in the first direction X. The slit ST may be omitted.

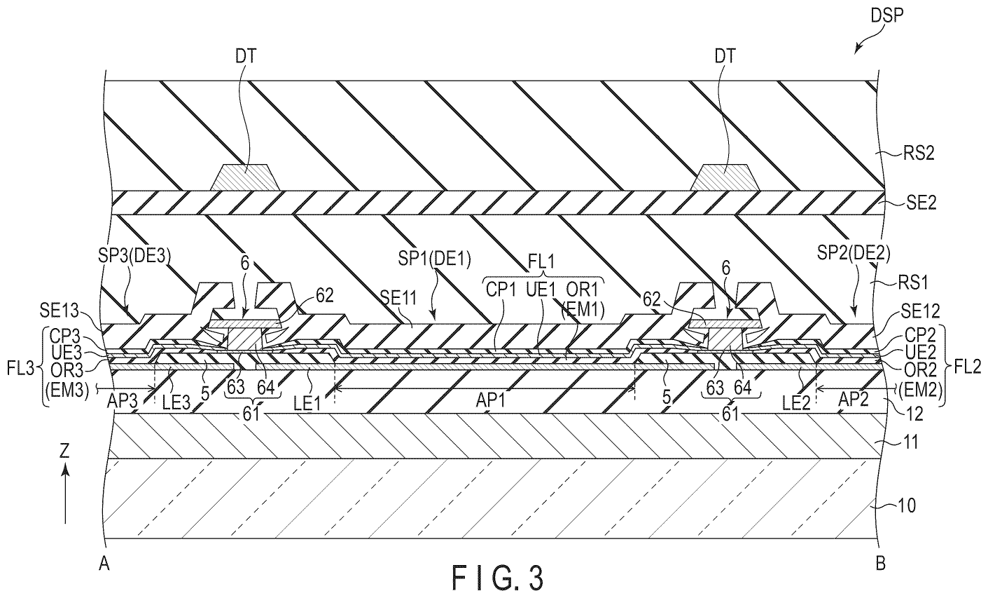

FIG. 3 is a schematic cross-sectional view of the display device DSP along the A-B line of FIG. 2.

A circuit layer 11 is provided on the substrate 10. The circuit layer 11 includes various circuits such as the pixel circuits 1 shown in FIG. 1, various lines such as the scanning lines GL, the signal lines SL, and the power lines PL, and various insulating layers.

The organic insulating layer 12 is provided on the circuit layer 11. For example, the organic insulating layer 12 is formed to planarize irregularities formed by the circuit layer 11.

The lower electrode LE1 of the subpixel SP1, the lower electrode LE2 of the subpixel SP2, and the lower electrode LE3 of the subpixel SP3 are provided on the organic insulating layer 12 and are spaced apart from each other.

The inorganic insulating layer 5 is provided on the organic insulating layer 12 and the lower electrodes LE1, LE2, and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The lower electrodes LE1, LE2, and LE3 are connected to the pixel circuits 1 of the respective subpixels SP1, SP2, and SP3 through the contact holes provided in the organic insulating layer 12. FIG. 3 omits the illustration of the contact holes in the organic insulating layer 12.

The partition 6 is formed in an overhang shape and comprises a lower portion 61 having conductivity and provided on the inorganic insulating layer 5 and an upper portion 62 provided on the lower portion 61.

In the illustrated example, the lower portion 61 comprises a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than the stem layer 64. The both end portions of the bottom layer 63 protrude relative to the side surfaces of the stem layer 64.

The upper portion 62 is provided on the stem layer 64. The upper portion 62 has the width greater than the stem layer 64. The both end portions of the upper portion 62 protrude relative to the side surfaces of the stem layer 64. In the present specification, the side surfaces of the stem layer 64 are assumed to be the side surfaces of the stem layer 64 that extend between the bottom layer 63 and the upper portion 62. In the illustrated example, the upper portion 62 has the width greater than the bottom layer 63. The bottom layer 63 may have a width greater than the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 has a cap layer CP1 and a sealing layer SE11. The subpixel SP2 has a cap layer CP2 and a sealing layer SE12. The subpixel SP3 has a cap layer CP3 and a sealing layer SE13. The cap layers CP1, CP2 and CP3 function as optical adjustment layers, which improve the extraction efficiency of light emitted from the respective organic layers OR1, OR2, and OR3. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The end portions of the sealing layers SE11, SE12 and SE13 are located above the partition 6. In the illustrated example, the sealing layer SE11 located on the partition 6 between the subpixels SP1 and SP2 is spaced apart from the sealing layer SE12 located on this partition 6. Further, the sealing layer SE11 located on the partition 6 between the subpixels SP1 and SP3 is spaced apart from the sealing layer SE13 located on this partition 6.

The stacked films FL1, FL2, and FL3 are not formed on the partition 6. Cavities are formed between the sealing layer SE11 and the partition 6, between the sealing layer SE12 and the partition 6, and between the sealing layer SE13 and the partition 6.

A transparent resin layer RS1 covers the partition 6 and the sealing layers SE11, SE12, and SE13. Further, the resin layer RS1 is filled into the cavity formed on the partition 6.

The sealing layer SE2 covers the resin layer RS1. A transparent resin layer RS2 is provided on the sealing layer SE2.

A detection electrode DT for achieving a touch sensor function of detecting contact or approach of an object to the display area DA is provided on the sealing layer SE2 and is covered with the resin layer RS2. For example, the detection electrode DT is a multilayer body having an aluminum layer formed of an aluminum-based material and a titanium layer formed of a titanium-based material. The touch sensor function is implemented by detecting a capacity variation in the sensor modules constituted by the detection electrode DT.

Each of the inorganic insulating layer 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃). For example, the inorganic insulating layer 5 is formed of a silicon oxynitride, and each of the sealing layers SE11, SE12, SE13, and SE2 is formed of a silicon nitride.

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. The stem layer 64 is formed of a material different from the bottom layer 63 and the upper portion 62, and is formed of, for example, an aluminum-based material such as aluminum or an aluminum compound.

The upper portion 62 of the partition 6 is formed of, for example, a conductive material.

However, the upper portion 62 may be formed of an insulating material. The upper portion 62 is formed of a material different from the lower portion 61. For example, the upper portion 62 is formed of a titanium-based material such as titanium or a titanium compound or an oxide conductive material such as an indium tin oxide (ITO).

Each of the lower electrodes LE1, LE2, and LE3 is, for example, a multilayer body having a transparent layer formed of an oxide conductive material such as an indium tin oxide (ITO) and a reflective layer formed of a metal material such as silver. For example, each of the lower electrodes LE1, LE2, and LE3 is a multilayer body having a reflective layer between a pair of transparent layers.

The organic layer OR1 has a light emitting layer EM1. The organic layer OR2 has a light emitting layer EM2. The organic layer OR3 has a light emitting layer EM3. The light emitting layers EM1, EM2, and EM3 are formed of materials different from each other. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. The light emitting layer EM1 may be formed of a material that emits light in a green wavelength. The light emitting layer EM2 may be formed of a material that emits light in a blue wavelength.

Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from each other.

The circuit layer 11, the organic insulating layer 12, the inorganic insulating layer 5, and the partition 6, which are illustrated, are provided across the display area DA and the surrounding area SA.

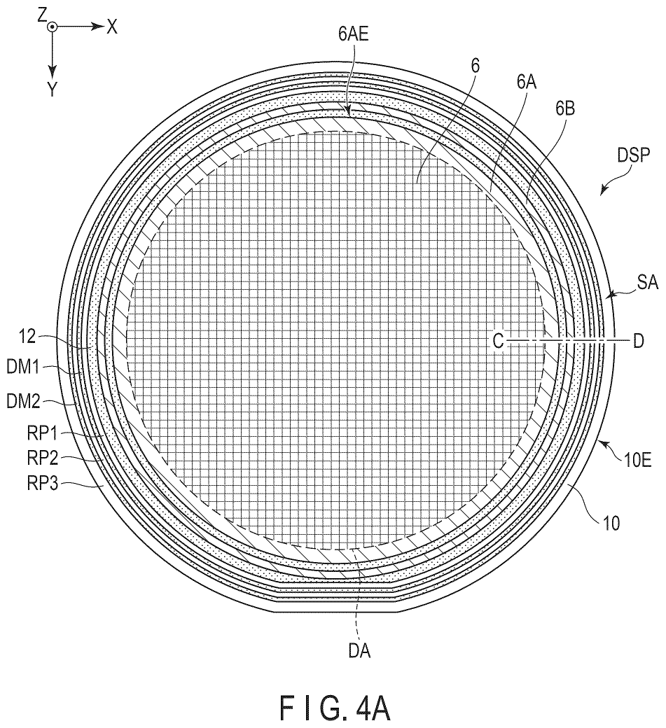

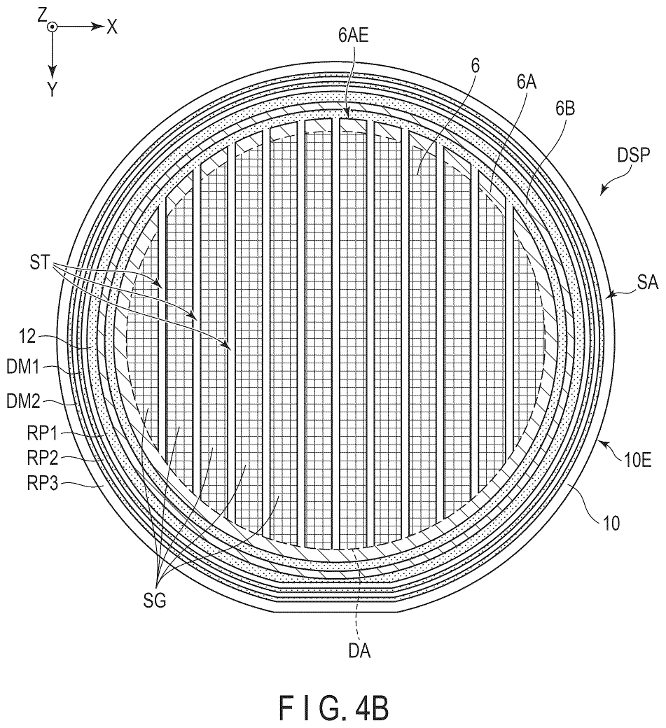

FIG. 4A is a schematic plan view of the display device DSP for describing a configuration example of the surrounding area SA.

As described above, the partition 6 is provided in the display area DA. The partitions 6A and 6B and the dam portions DM1 and DM2 are provided in the surrounding area SA and are located between the display area DA and the edge potion 10E of the substrate 10.

The partition 6A is formed to surround the display area DA and be electrically connected to the partition 6. The partition 6B is formed to surround the partition 6A and be spaced apart from the partition 6A. In the illustrated example, an outer edge portion 6AE facing the partition 6B of the partition 6A and the partition 6B are formed continuously without being cut. The partition 6B may be omitted in the configuration in which the outer edge portion 6AE is formed continuously without being cut.

Each of these partitions 6, 6A, and 6B overlaps the organic insulating layer 12 in plan view. The cross-sectional shapes of the partitions 6A and partitions 6B are the same overhang shape as the partition 6. This shape will be described later.

The dam portions DM1 and DM2 are both formed in a ring shape. The dam portion DM1 is formed to surround the display area DA and be spaced from the organic insulating layer 12. The dam portion DM2 is formed to surround the dam portion DM1 and be spaced apart from the dam portion DM1. The shapes of the dam portions DM1 and DM2 are not limited to the illustrated example. The number of the dam portions may be one or three or more.

Each of removed portions RP1, RP2, and RP3 that penetrate the organic insulating layer 12 is formed in a ring shape. The removed portion RP1 is located between the organic insulating layer 12 and the dam portion DM1 and surrounds the display area DA and the partitions 6, 6A, and 6B. The removed portion RP2 is located between the dam portions DM1 and DM2 and surrounds the removed portion RP1. The removed portion RP3 extends from the dam portion DM2 to the edge portion 10E and surrounds the removed portion RP2.

FIG. 4B is a schematic plan view of the display device DSP for describing another configuration example of the surrounding area SA.

The configuration example shown in FIG. 4B differs from the configuration example shown in FIG. 4A in that the slit ST of the partition 6 extends to the partition 6A. Further, the outer edge portion 6AE of the partition 6A facing the partition 6B is formed discontinuously. In contrast, the partition 6B is formed continuously without being cut.

Although not shown, the partition 6B may be formed discontinuously when the outer edge portion 6AE is formed continuously as shown in FIG. 4A. That is, at least one of the outer edge portion 6AE and the partition 6B is formed continuously. This configuration can block a moisture penetration path from the surrounding area SA toward the display area DA as described later.

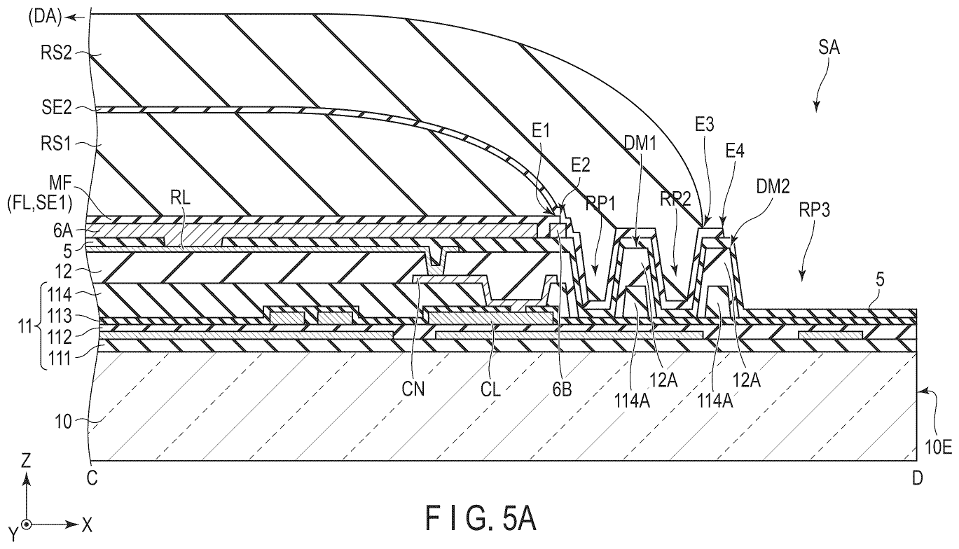

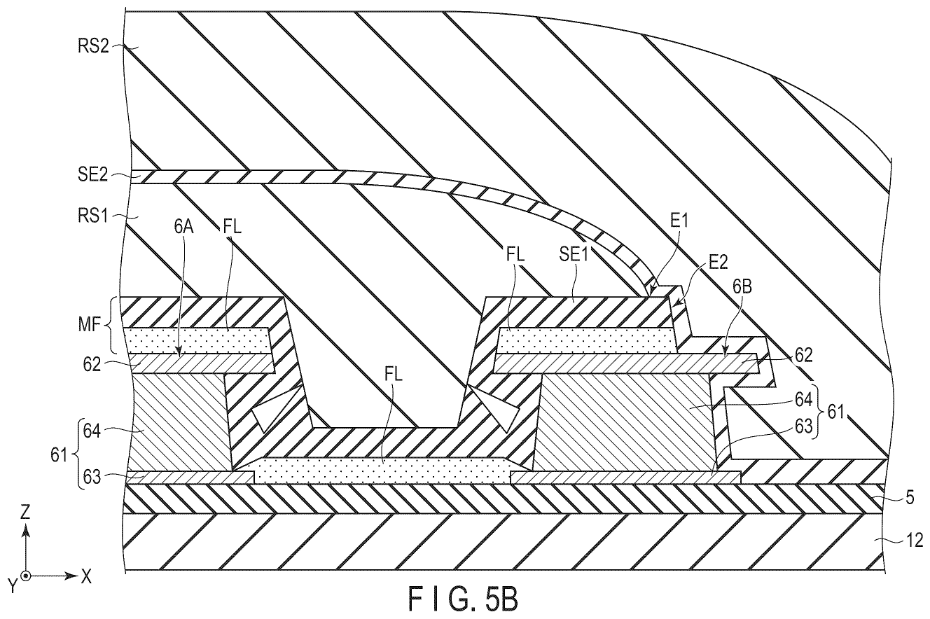

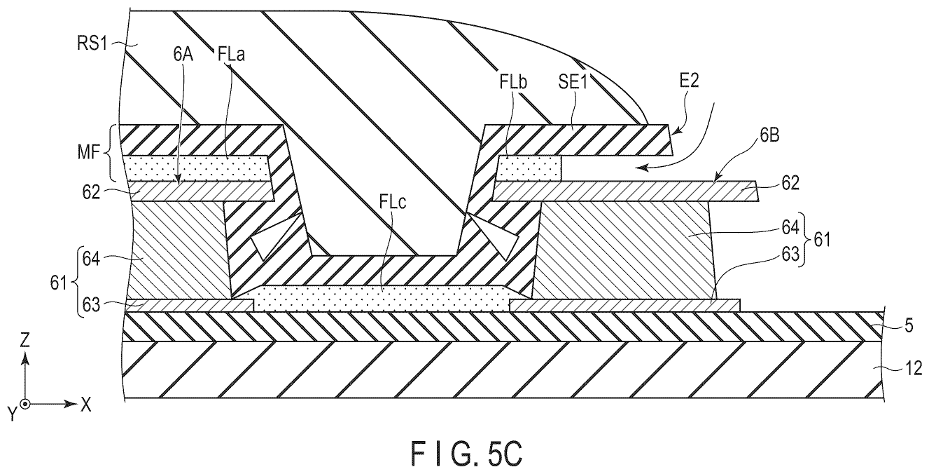

FIG. 5A is a schematic cross-sectional view of the display device DSP along the C-D line of the surrounding area SA shown in FIG. 4A.

The circuit layer 11 shown in FIG. 3 further comprises insulating layers 111, 112, 113, and 114, a power supply line CL, and a connection electrode CN. Though not described in detail, the circuit layer 11 comprise various lines and various electrodes.

The insulating layer 111 is provided on the substrate 10. The insulating layer 112 is provided on the insulating layer 111. The insulating layer 113 is provided on the insulating layer 112. The insulating layer 114 is provided on the insulating layer 113. The insulating layers 111, 112, and 113 are formed of inorganic insulating materials, extend to the edge portion 10E of the substrate 10, and are provided directly under the dam portions DM1 and DM2. The insulating layer 114 is formed of an organic insulating material and is covered with the organic insulating layer 12.

The inorganic insulating layer 5 covers the organic insulating layer 12. The inorganic insulating layer 5 covers the insulating layer 113 in the removed portion RP1 between the organic insulating layer 12 and the dam portion DM1. The partitions 6A and 6B are provided on the inorganic insulating layer 5 above the insulating layer 114 and the organic insulating layer 12.

The power supply line CL is a line for supplying the partition 6 with common voltage and is provided between the insulating layers 112 and 113. The connection electrode CN is provided between the insulating layer 114 and the organic insulating layer 12 and contacts the power supply line CL through a through hole in the insulating layer 113 and a through hole in the insulating layer 114. A relay electrode RL is provided between the organic insulating layer 12 and the inorganic insulating layer 5 and contacts the connection electrode CN through a through hole in the organic insulating layer 12. For example, this relay electrode RL is formed of the same material as the lower electrode LE1 and the like. The partition 6A contacts the relay electrode RL through a through hole in the inorganic insulating layer 5. This causes the partition 6A and the partition 6 of the display area DA to be electrically connected to the power supply line CL.

Each of the dam portions DM1 and DM2 is provided on the insulating layer 113 and is covered with the inorganic insulating layer 5. The inorganic insulating layer 5 covers the insulating layer 113 in the removed portion RP2 between the dam portions DM1 and DM2 and in the removed portion RP3 between the dam portion DM2 and the edge portion 10E.

Each of the dam portions DM1 and DM2 comprise a first layer 114A and a second layer 12A. The first layer 114A is formed at the same time as the insulating layer 114 using the same material as the insulating layer 114 and has the same thickness as the insulating layer 114. The second layer 12A is formed at the same time as the organic insulating layer 12 using the same material as the organic insulating layer 12 and has the same thickness as the organic insulating layer 12. Here, the thickness corresponds to the length along the third direction Z.

The first layer 114A is provided on the insulating layer 113. The second layer 12A covers the first layer 114A and is covered with the inorganic insulating layer 5. Each of these first layer 114A and the second layer 12A is formed of the same type of organic insulating materials, for example, a polyimide.

In the surrounding area SA, a multilayer film MF is located above the organic insulating layer 12, is provided on the partitions 6A and 6B and on the inorganic insulating layer 5 between the partitions 6A and 6B. The multilayer film MF is not provided on any of the removed portions RP1, RP2, and RP3 and the dam portions DM1 and DM2.

The multilayer film MF comprises a stacked film FL and a sealing layer SE1 provided on the stacked film FL.

Here, the stacked film FL is any one of the stacked films FL1, FL2, and FL3 shown in FIG. 3. For example, when the stacked film FL is the stacked film FL3, the stacked film FL is formed as a stacked layer body of thin films formed of the same material as each of the organic layer OR3, the upper electrode UE3, and the cap layer CP3.

Here, the sealing layer SE1 is any one of the sealing layers SE11, SE12, and SE13 shown in FIG. 3. For example, when the stacked film FL is the stacked film FL3, the sealing layer SE1 is the sealing layer SE13.

The resin layer RS1 is provided on the multilayer film MF. An edge portion E1 of the resin layer RS1 is located directly above the multilayer film MF (or the sealing layer SE1). The resin layer RS1 is not provided on any of the removed portions RP1, RP2, and RP3 and the dam portions DM1 and DM2.

Each of the edge portion E1 of the resin layer RS1 and the edge portion E2 of the multilayer film MF is located directly above the organic insulating layer 12. That is, the edge portions E1 and E2 are located between the display area DA and the removed portion RP1. Further, the edge portions E1 and E2 are located directly above the partition 6B. In the illustrated example, the edge portion E1 is located inward of the edge portion E2 (on the side toward the display area DA). The edge portion E1 may be located directly above the edge portion E2. The edge portion E1 is not located outside the edge portion E2 (on the side toward the edge portion 10E of the substrate 10). That is, the resin layer RS1 is not provided to extend beyond the multilayer film MF.

The edge portion E2 of the multilayer film MF here corresponds to the edge portion of the sealing layer SE1 of the thin films that constitute the multilayer film MF. The edge portions of the stacked film FL do not necessarily overlap the edge portions of the sealing layer SE1 in the third direction Z and could be located inward of the edge portions of the sealing layer SE1.

The sealing layer SE2 covers the resin layer RS1. The sealing layer SE2 extends outward beyond the edge portions E1 and E2, covers the partition 6B, and contacts the inorganic insulating layer 5 in the removed portion RP1, the dam portion DM1, and the removed portion RP2. In the illustrated example, an edge portion E4 of the sealing layer SE2 is located inward of the edge portion 10E and overlaps the dam portion DM2.

This configuration causes the resin layer RS1 to be surrounded and sealed by the sealing layers SE1 and SE2. This configuration prevents the moisture penetration into the resin layer RS1.

The resin layer RS2 is provided on the sealing layer SE2 and fills the removed portions RP1 and RP2. In the illustrated example, the edge portion E3 of the resin layer RS2 overlaps the dam portion DM2 and is located inward of the edge portion E4.

As shown in the figure, the display device DSP in which the removed portion RP3 extends to the edge portion 10E of the substrate 10 can be extracted from the mother substrate by cutting the mother substrate using laser beam.

FIG. 5B is a cross-sectional view showing the vicinity of the edge portions E1 and E2 shown in FIG. 5A in an enlarged manner. FIG. 5B omits the illustration of the components below the organic insulating layer 12.

In the same manner as the partition 6 shown in FIG. 3, each of the partitions 6A and 6B comprises the lower portion 61 and the upper portion 62. The lower portion 61 comprises the bottom layer 63 provided on the inorganic insulating layer 5 and the stem layer 64 provided between the bottom layer 63 and the upper portion 62. The both end portions of the bottom layer 63 protrude relative to the side surfaces of the stem layer 64. The both end portions of the upper portion 62 protrude relative to the side surfaces of the stem layer 64.

The stacked film FL is divided into a portion provided on the partition 6A, a portion provided on the partition 6B, and a portion provided on the inorganic insulating layer 5 between the partitions 6A and 6B. The partition 6B is electrically connected to the partition 6A via a thin film formed of the same material as the upper electrode included in the stacked film FL.

The sealing layer SE1 covers the stacked film FL above the partition 6A and covers the partition 6A. Further, the sealing layer SE1 covers the stacked film FL between the partitions 6A and 6B. Further, the sealing layer SE1 overlaps the stacked film FL above the partition 6B. The edge portion of the sealing layer SE1, in other words, the edge portion E2 of the multilayer film MF is located directly above the partition 6B. This causes the outside of the partition 6B (the side opposite to the partition 6A) to be exposed from the sealing layer SE1.

The resin layer RS1 is provided on the sealing layer SE1 and is filled between the partitions 6A and 6B. The edge portion E1 of the resin layer RS1 is located directly above the partition 6B. This causes the outside of the partition 6B to be exposed from the resin layer RS1.

The sealing layer SE2 covers the resin layer RS1. Further, the sealing layer SE2 contacts the edge portion E2 outward of the edge portion E1, contacts the partition 6B outward of the edge portion E2, and covers the outside of the partition 6B.

FIG. 5C is a view for describing an influence of moisture penetration in the vicinity of the edge portion E2.

A stacked film FLb provided on the partition 6B is not covered with the sealing layer SE1 and is exposed from the sealing layer SE1 in the vicinity of the edge portion E2. Thus, the stacked film FLb may be eliminated by moisture penetration from the vicinity of the edge portion E2. In contrast, each of a stacked film FLa on the partition 6A and a stacked film FLc provided between the partitions 6A and 6B is covered with the sealing layer SE1 and is separated from the stacked film FLb. Thus, the stacked films FLa and FLc are not susceptible to damage by moisture penetration from the vicinity of the edge portion E2. That is, the moisture penetration path from the vicinity of the edge portion E2 toward the display area DA is blocked, and thus the stacked film FL of the display area DA is protected from moisture.

Further, as described with reference to FIG. 4A and FIG. 4B, at least one of the outer edge portion 6AE of the partition 6A and the partition 6B is formed continuously. Thus, the stacked film FL is separated by the partitions 6A and 6B around the entire circumference of the display device DSP. This enables blocking the moisture penetration path from the surrounding area SA toward the display area DA in the entire circumference of the display device DSP. This suppresses decreases in reliability.

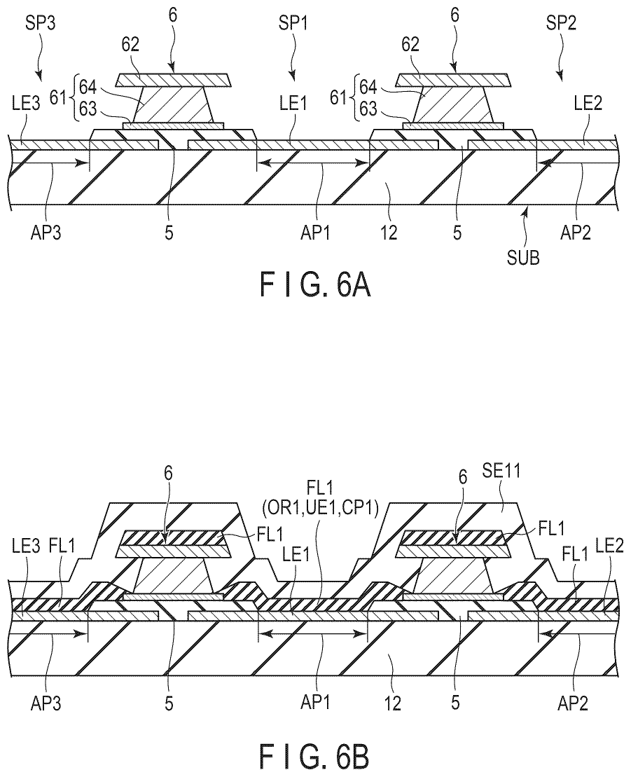

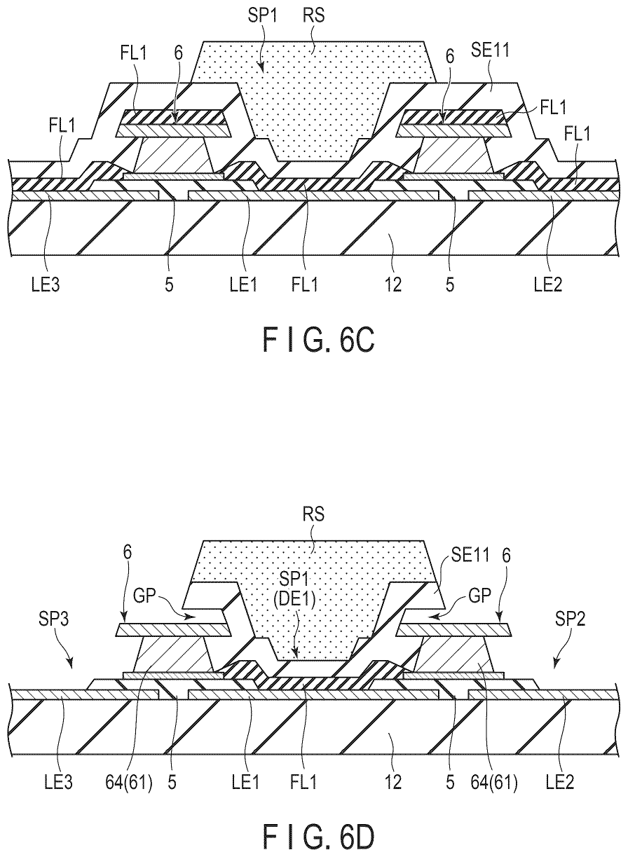

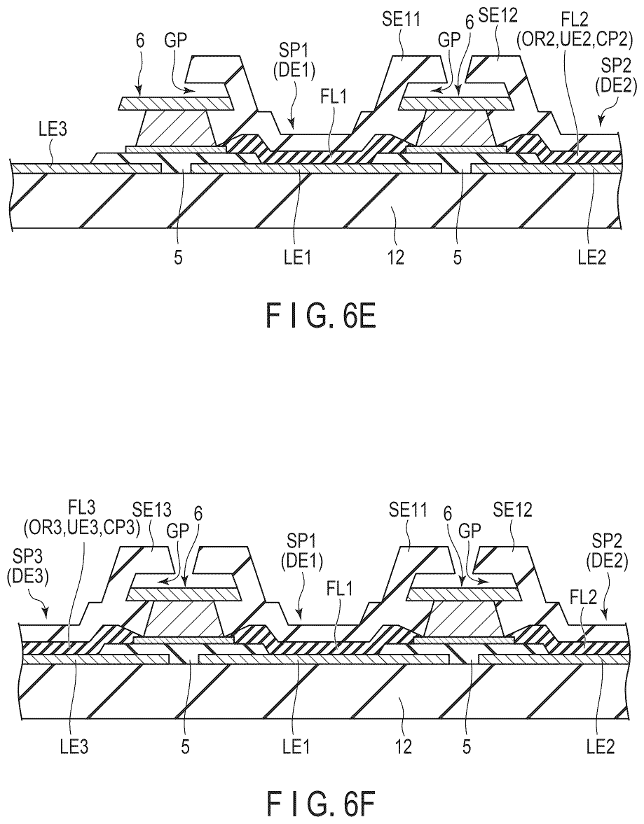

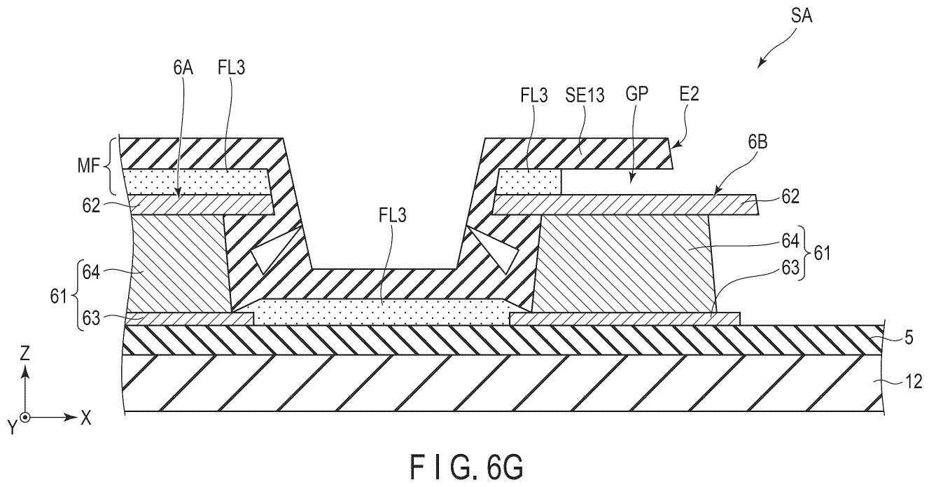

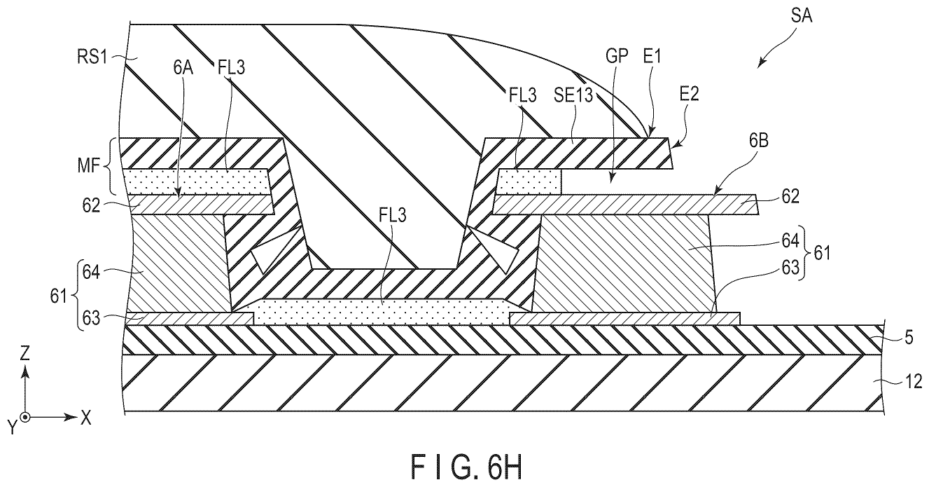

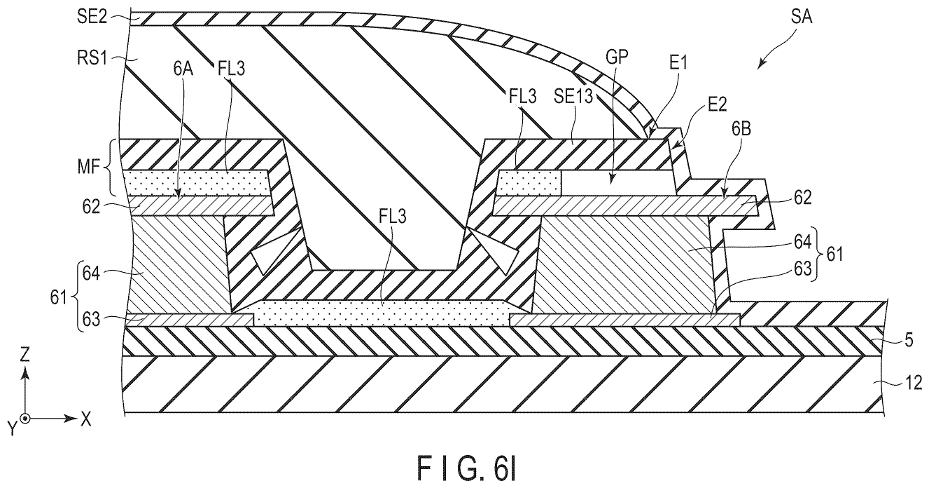

Next, a manufacturing method of the display device DSP will be described. FIG. 6A to FIG. 6F are cross-sectional views of a processing substrate SUB along the A-B line of FIG. 2 and omits elements below the organic insulating layer 12.

First, as shown in FIG. 6A, the processing substrate SUB is prepared. The process of preparing the processing substrate SUB includes the process of forming the lower electrode LE1 of the subpixel SP1, the lower electrode LE2 of the subpixel SP2, and the lower electrode LE3 of the subpixel SP3 on the organic insulating layer 12, the process of forming the inorganic insulating layer 5 having the apertures AP1, AP2, and AP3 overlapping the respective lower electrodes LE1, LE2, and LE3, and the process of forming the partition 6 having the lower portion 61 located on the inorganic insulating layer 5 and the upper portion 62 located on the lower portion 61. The partition 6 may be formed after the formation of the inorganic insulating layer 5 having the apertures AP1, AP2, and AP3. Alternatively, the apertures AP1, AP2, and AP3 may be formed on the inorganic insulating layer 5 after the formation of the partition 6. In the process of forming the partition 6, the partitions 6A and 6B of the surrounding area SA are formed as well.

Subsequently, the display element DE1 is formed.

First, as shown in FIG. 6B, the stacked film FL1 is formed on the processing substrate SUB by performing vapor deposition using the partition 6 as a mask. The stacked film FL1 includes the organic layer OR1 including the light emitting layer EM1, the upper electrode UE1, and the cap layer CP1. The organic layer OR1, the upper electrode UE1, and the cap layer CP1 are successively formed by an evaporation device in a vacuum state. The stacked film FL1 is divided by the partition 6 having an overhang shape.

Subsequently, the sealing layer SE11 continuously covering the stacked film FL1 and the partition 6 is formed. The sealing layer SE11 is formed by depositing inorganic insulating materials (for example, a silicon nitride) on the processing substrate SUB in a chemical vapor deposition (CVD) device.

The stacked film FL1 and the sealing layer SE11 are substantially formed in the entire processing substrate SUB and are provided in the subpixels SP2 and SP3 as well as the subpixel SP1 in the display area DA.

Subsequently, as shown in FIG. 6C, a resist RS patterned into a predetermined shape is formed on the sealing layer SE11. The resist RS overlaps the subpixel SP1 and a portion of the partition 6 around the subpixel SP1.

Subsequently, as shown in FIG. 6D, patterning is performed on the sealing layer SE11 and the stacked film FL1 using the resist RS as a mask. After removing the sealing layer SE11 exposed from the resist RS, the cap layer CP1, the upper electrode UE1, and the organic layer OR1 included in the stacked film FL1 are removed in series, by performing various types of etching using the resist RS as a mask.

These patterning processes cause the lower electrode LE2 of the subpixel SP2 and the lower electrode LE3 of the subpixel SP3 to be exposed. Further, the stacked film FL1 and the sealing layer SE11 are removed in the surrounding area SA as well.

Subsequently, the resist RS is removed. Thus, the display element DE1 in the subpixel SP1 is formed. Further, in the illustrated example, the stacked film FL1 stacked on the partition 6 is removed in the processes between the patterning of the stacked film FL1 and the removal of the resist RS. Thus, a cavity GP is formed between the sealing layer SE11 and the partition 6.

Subsequently, as shown in FIG. 6E, the display element DE2 is formed. The procedure of forming the display element DE2 is the same as that of forming the display element DE1. That is, the stacked film FL2 is formed on the lower electrode LE2. The stacked film FL2 includes the organic layer OR2 having the light emitting layer EM2, the upper electrode UE2, and the cap layer CP2. Subsequently, the sealing layer SE12 is formed on the stacked film FL2. Subsequently, a resist is formed on the sealing layer SE12. Then, patterning using this resist as a mask is performed. This sequentially removes the sealing layer SE12 and the stacked film FL2 exposed from the resist. Subsequently, the resist is removed.

Thus, the display element DE2 in the subpixel SP2 is formed and the lower electrode LE3 of the subpixel SP3 is exposed. In the illustrated example, the stacked film FL2 on the partition 6 is removed at the time of patterning. Thus, a cavity GP between the sealing layer SE12 and the partition 6 is formed.

Subsequently, as shown in FIG. 6F, the display element DE3 is formed. The procedure of forming the display element DE3 is the same as that of forming the display element DE1. That is, the stacked film FL3 is formed on the lower electrode LE3. The stacked film FL3 includes the organic layer OR3 having the light emitting layer EM3, the upper electrode UE3, and the cap layer CP3. Subsequently, the sealing layer SE13 is formed on the stacked film FL3. Subsequently, a resist is formed on the sealing layer SE13. Then, patterning using this resist as a mask is performed. This sequentially removes the sealing layer SE13 and the stacked film FL3 exposed from the resist. Subsequently, the resist is removed.

Thus, the display element DE3 in the subpixel SP3 is formed. In the illustrated example, the stacked film FL3 on the partition 6 is removed at the time of patterning. Thus, the cavity GP between the sealing layer SE13 and the partition 6 is formed.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

Next, the following descriptions focus on the surrounding area SA. FIG. 6G to FIG. 6I omit the illustration of the components below the organic insulating layer 12.

In the example shown in FIG. 6G, the stacked film FL3 and the sealing layer SE13 for forming the display element DE3 are provided as the multilayer film MF in the surrounding area SA. Further, in the process of forming the display element DE3, at least a portion of the stacked film FL3 on the partition 6B is removed during patterning of the stacked film FL3 and the sealing layer SE13. Thus, the cavity GP is formed between the partition 6B and the sealing layer SE13. The stacked film FL3 on the partition 6A and the stacked film FL3 between the partitions 6A and 6B is covered with the sealing layer SE13.

Then, as shown in FIG. 6H, an organic insulating material is applied and cured to form the resin layer RS1. At this time, the organic insulating material coated on the sealing layer SE13 remains on the sealing layer SE13 due to its surface tension. In the present embodiment, this eliminates the need of providing a plurality of dam portions for blocking the spread of the resin layer RS1 in the surrounding area SA. Thus, compared to configurations in which dam portions are provided to prevent the resin layer RS1 from spreading, the width of the surrounding area SA, in other words, the width from the edge portion of the organic insulating layer 12 to the edge portion of the substrate 10 can be made smaller.

Further, compared to configurations in which the resin layer RS1 fills the removed portions, the formation of undesirable recesses or steps caused by insufficient application of the organic insulating material is suppressed. Further, the upper surface of the resin layer RS1 is a convex in the surrounding area SA and is formed as a smooth surface including almost no local recess portions.

Then, as shown in FIG. 6I, the sealing layer SE2 is formed by stacking an inorganic insulating material (for example, a silicon nitride). The sealing layer SE2 is formed beyond the edge portion E1 of the resin layer RS1 and the edge portion E2 of the sealing layer SE1, covers the partition 6B, contacts the inorganic insulating layer 5, and seals the resin layer RS1. Further, the cavity GP is blocked by the sealing layer SE2 in the vicinity of the edge portion E2.

Then, a metal layer is formed on the sealing layer SE2 and patterned to form the detection electrode DT. If a recess portion is formed in the base resin layer RS1 in the formation of the detection electrode DT, short-circuiting of adjacent detection electrodes DT may occur due to patterning failure of the metal layer formed in the recess portion.

As described above, the resin layer RS1 in the present embodiment is formed to have a smooth upper surface. This suppresses the patterning failure of the metal layer and the deformation of the detection electrode DT.

Then, an organic insulating material is applied and cured. Thus, the resin layer RS2 is formed. At this time, as shown in FIG. 5A, the spread of the resin layer RS2 is dammed by the dam portions DM1 and DM2. The resin layer RS2 fills the removed portions RP1 and RP2.

The display device DSP is completed through these processes.

Next, another configuration example will be described. The same elements as in the above configuration example are denoted by the same reference numerals and their detailed explanations are omitted in some cases.

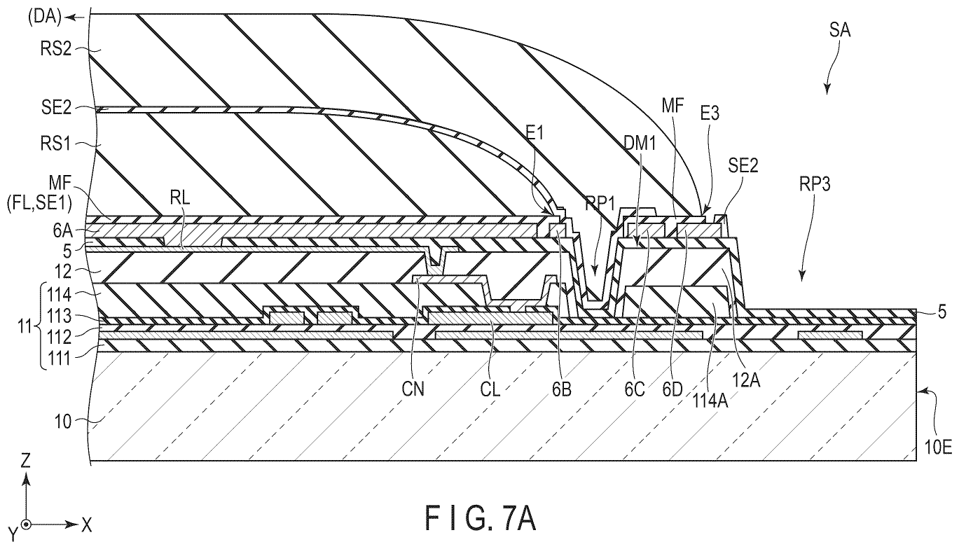

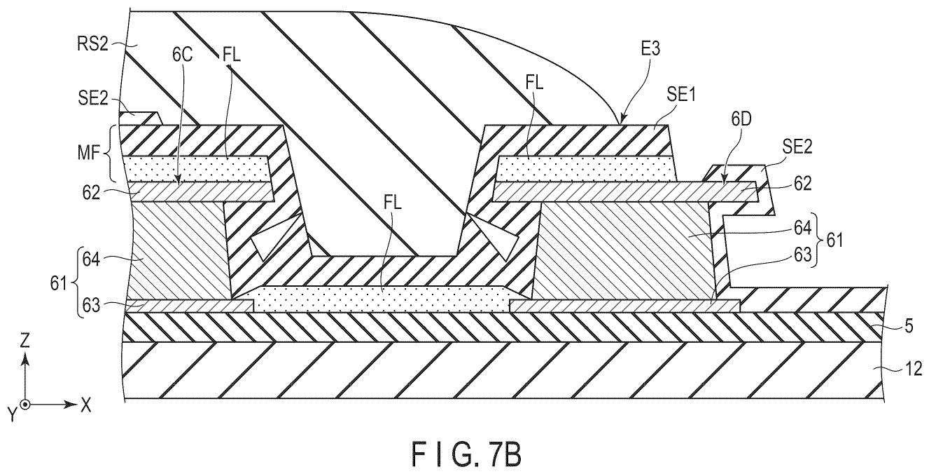

FIG. 7A is a cross-sectional view showing another configuration example of the display device DSP along the C-D line of the surrounding area SA shown in FIG. 4A.

The configuration example shown in FIG. 7A differs from the configuration example shown in FIG. 5A in that the multilayer film MF is provided on the dam portion DM1, and the edge portion E3 of the resin layer RS2 is located directly above this multilayer film MF (or the sealing layer SE1). In the illustrated example, in the surrounding area SA, one dam portion DM1 is provided, but the dam portion DM2 and the removed portion RP2 between the dam portions DM1 and DM2 shown in FIG. 5A do not exist. Outside the dam portion DM1, the removed portion RP3 extends to the edge portion 10E of the substrate 10.

As described with reference to FIG. 4A, the dam portion DM1 is formed so to surround the display area DA and be spaced apart from the organic insulating layer 12. The dam portion DM1 is provided on the insulating layer 113 and is covered with the inorganic insulating layer 5. The partitions 6C and 6D are provided on the inorganic insulating layer 5 above the dam portion DM1. The partition 6C is formed to surround the removed portion RP1. The partition 6D is formed to be spaced apart from the partition 6C and surround the partition 6C. The cross-sectional shapes of the partitions 6C and partitions 6D are the same overhang shape as the partition 6. This shape will be described later.

The multilayer film MF is not provided on the removed portion RP1 between the organic insulating layer 12 and the dam portion DM1. That is, the multilayer film MF is divided into a portion provided above the organic insulating layer 12 and a portion provided above the dam portion DM1. The multilayer film MF is provided on the partitions 6C and 6D above the dam portion DM1.

The resin layer RS1 is provided on the multilayer film MF above the organic insulating layer 12. The edge portion E1 of the resin layer RS1 is located directly above the organic insulating layer 12 and the multilayer film MF. The resin layer RS1 is not provided on the removed portions RP1 and RP3 and the dam portion DM1.

The sealing layer SE2 covers the resin layer RS1 and, in the removed portion RP1, contacts the inorganic insulating layer 5 and seals the resin layer RS1. Further, the sealing layer SE2 is provided on the multilayer film MF above the dam portion DM1 to causes a portion of the multilayer film MF to be exposed.

The resin layer RS2 is provided on the sealing layer SE2 and fills the removed portion RP1. The resin layer RS2 is provided above the dam portion DM1 and contacts the multilayer film MF exposed from the sealing layer SE2. The edge portion E3 of the resin layer RS2 is located directly above the dam portion DM1.

FIG. 7B is a cross-sectional view showing the vicinity of the edge portion E3 shown in FIG. 7A in an enlarged manner. FIG. 7B omits the illustration of the components below the organic insulating layer 12.

In the same manner as the partition 6 shown in FIG. 3, each of the partitions 6C and 6D comprises the lower portion 61 and the upper portion 62. The lower portion 61 comprises the bottom layer 63 provided on the inorganic insulating layer 5 and the stem layer 64 provided between the bottom layer 63 and the upper portion 62. The both end portions of the bottom layer 63 protrude relative to the side surfaces of the stem layer 64. The both end portions of the upper portion 62 protrude relative to the side surfaces of the stem layer 64.

The stacked film FL is divided into a portion provided on the partition 6C, a portion provided on the partition 6D, and a portion provided on the inorganic insulating layer 5 between the partitions 6C and 6D.

The sealing layer SE1 covers the stacked film FL above the partition 6C and covers the partition 6C. Further, the sealing layer SE1 covers the stacked film FL between the partitions 6C and 6D. Further, the sealing layer SE1 overlaps the stacked film FL above the partition 6D.

The sealing layer SE2 is provided on the sealing layer SE1 above the partition 6C. The sealing layer SE2 causes the sealing layer SE1 to be exposed between the partitions 6C and 6D. As shown in FIG. 7A, the resin layer RS1 is neither provided on the dam portion DM1 nor interposed between the sealing layer SE1 and the edge portion E3.

The resin layer RS2 is provided on the sealing layer SE2 above the partition 6C and is provided on the sealing layer SE1 exposed from the sealing layer SE2. Further, the resin layer RS2 is filled between the partitions 6C and 6D. Further, the resin layer RS2 is provided on the sealing layer SE1 above the partition 6D. The edge portion E3 of the resin layer RS2 is located directly above the sealing layer SE1. In the illustrated example, the edge portion E3 of the resin layer RS2 is located directly above the partition 6D.

This configuration example can achieve the same effect as in the above configuration examples.

Further, as in the configuration example, the resin layer RS2 of the illustrated configuration example is formed by applying an organic insulating material. At this time, directly above the dam portion DM1, the organic insulating material coated on the sealing layer SE1 remains on the sealing layer SE1 due to its surface tension. In the present embodiment, this eliminates the need of providing a plurality of dam portions for blocking the spread of the resin layer RS2 in the surrounding area SA.

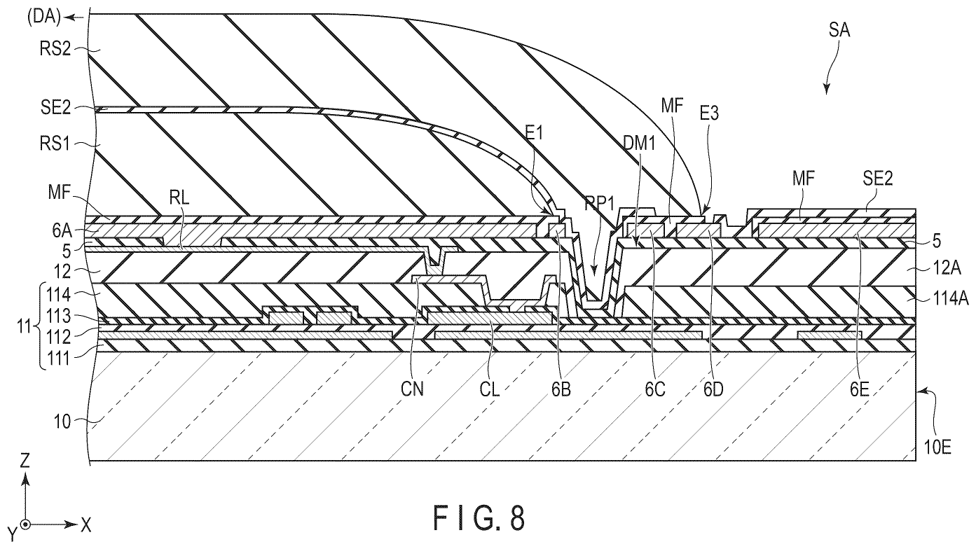

FIG. 8 is a cross-sectional view showing another configuration example of the display device DSP along the C-D line of the surrounding area SA shown in FIG. 4A.

The configuration example shown in FIG. 8 differs from the configuration example shown in FIG. 7A in that the dam portion DM1 extends to the edge portion 10E of the substrate 10. That is, the removed portion RP3 shown in FIG. 7A does not exist.

The partition 6E is provided on the inorganic insulating layer 5 above the dam portion DM1. The partition 6E is formed to be spaced apart from the partition 6D and surround the partition 6D. Though not described in detail, the cross-sectional shape of the partition 6D is the same overhang shape as the partition 6.

Above the dam portion DM1, the multilayer film MF is divided into a portion provided on the partitions 6C and 6D and a portion provided on the partition 6E.

The edge portion E1 of the resin layer RS1 is located directly above the organic insulating layer 12 and the multilayer film MF.

The sealing layer SE2 contacts the inorganic insulating layer 5 and seals the resin layer RS1 in the removed portion RP1. Further, the sealing layer SE2 causes a portion of the multilayer film MF provided on the partitions 6C and 6D to be exposed above the dam portion DM1. Further, the sealing layer SE2 covers the multilayer film MF provided on the partition 6E.

The resin layer RS2 is provided on the sealing layer SE2 and fills the removed portion RP1. The resin layer RS2 contacts the multilayer film MF exposed from the sealing layer SE2 above the dam portion DM1. The edge portion E3 of the resin layer RS2 is located directly above the dam portion DM1 and the multilayer film MF exposed from the sealing layer SE2.

This configuration example achieves the same effects as the configuration examples described with reference to FIG. 7A and FIG. 7B.

As shown in the figure, the display device DSP in which the dam portion DM1 extends to the edge portion 10E of the substrate 10 can be extracted from the mother substrate by cutting the mother substrate by scribing.

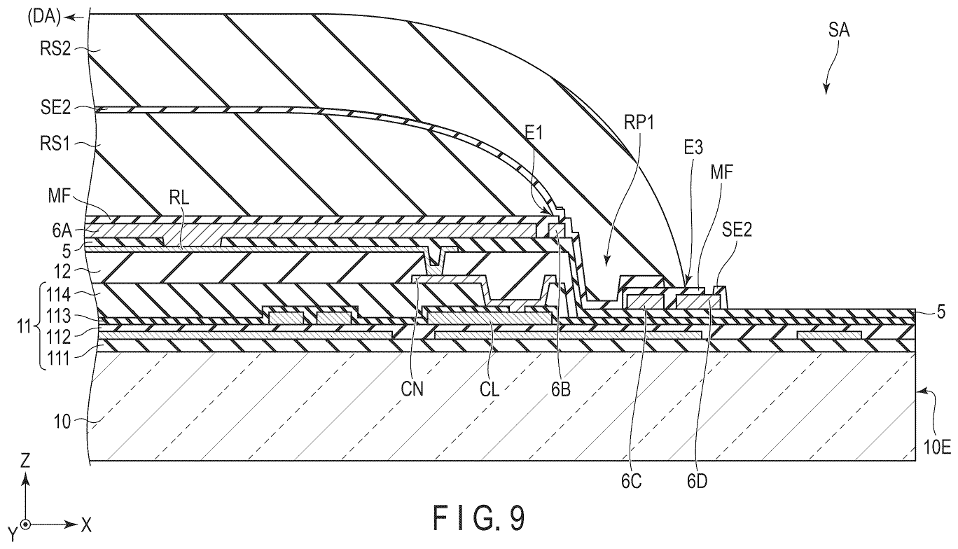

FIG. 9 is a cross-sectional view showing another configuration example of the display device DSP along the C-D line of the surrounding area SA shown in FIG. 4A.

The configuration example shown in FIG. 9 differs from the configuration example shown in FIG. 7A in that the organic insulating layer 12 is not interposed between the edge portion E3 of the resin layer RS2 and the substrate 10. That is, the removed portion RP1 shown in FIG. 7A extends to the edge portion 10E of the substrate 10, and the dam portion DM1 and the removed portion RP3 do not exist.

The inorganic insulating layer 5 covers the insulating layer 113 in the removed portion RP1. The partitions 6C and 6D are provided on the inorganic insulating layer 5. The multilayer film MF is divided into a portion provided above the organic insulating layer 12 and a portion provided above the removed portion RP1. The multilayer film MF in the removed portion RP1 is provided on the partitions 6C and 6D.

The edge portion E1 of the resin layer RS1 is located directly above the organic insulating layer 12 and the multilayer film MF.

The sealing layer SE2 contacts the inorganic insulating layer 5 and seals the resin layer RS1 in the removed portion RP1. The sealing layer SE2 is provided on the multilayer film MF in the removed portion RP1 and causes a portion of the multilayer film MF to be exposed.

The resin layer RS2 is provided on the sealing layer SE2 and contacts the multilayer film MF exposed from the sealing layer SE2 in the removed portion RP1. The edge portion E3 of the resin layer RS2 is located in the removed portion RP1 and is located directly above the multilayer film MF exposed from the sealing layer SE2.

This configuration example achieves the same effects as the configuration examples described with reference to FIG. 7A and FIG. 7B.

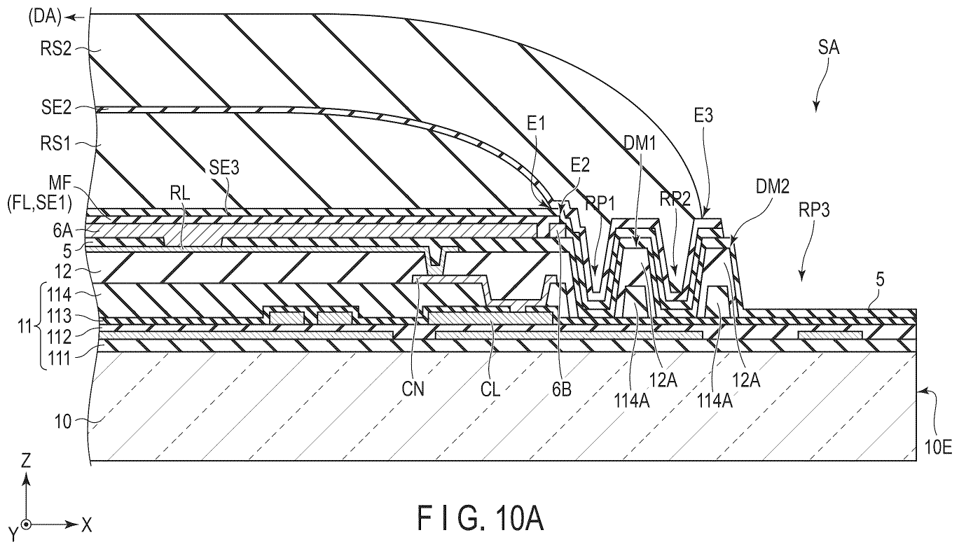

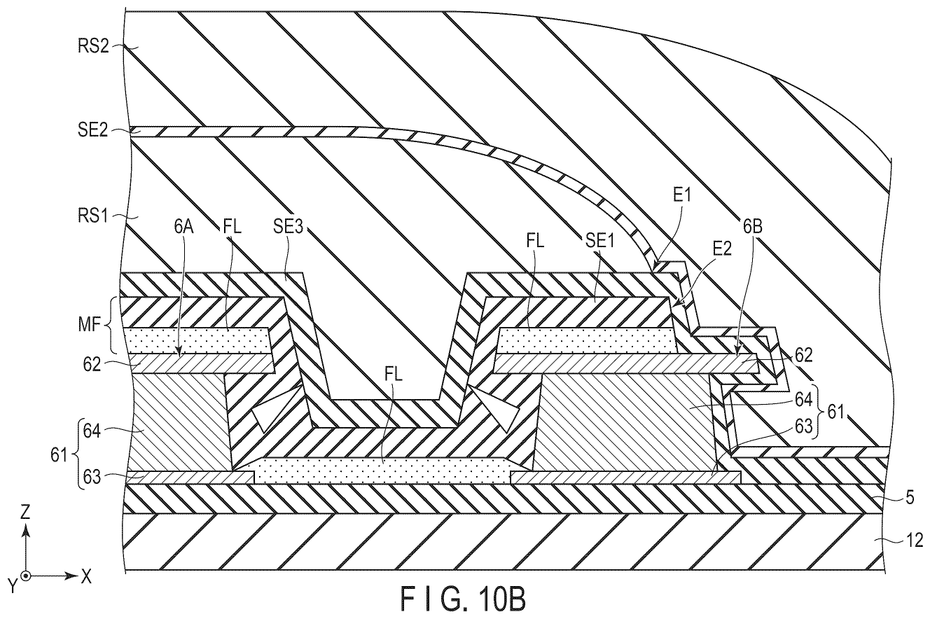

FIG. 10A is a cross-sectional view showing another configuration example of the display device DSP along the C-D line of the surrounding area SA shown in FIG. 4A.

The configuration example shown in FIG. 10A differs from the configuration example shown in FIG. 5A in that the sealing layer SE3 is provided between the multilayer film MF and the resin layer RS1. The sealing layer SE3 covers the multilayer film MF, covers the partition 6B outside the edge portion E2, and contacts the inorganic insulating layer 5. The sealing layer SE2 covers the resin layer RS1, contacts the sealing layer SE3 outside the edge portion E1, and seals the resin layer RS1.

FIG. 10B is a cross-sectional view showing the vicinity of the edge portions E1 and E2 shown in FIG. 10A in an enlarged manner. FIG. 10B omits the illustration of the components below the organic insulating layer 12.

The stacked film FL is divided into a portion provided on the partition 6A, a portion provided on the partition 6B, and a portion provided on the inorganic insulating layer 5 between the partitions 6A and 6B.

The sealing layer SE1 covers the stacked film FL above the partition 6A and covers the partition 6A. Further, the sealing layer SE1 covers the stacked film FL between the partitions 6A and 6B. Further, the sealing layer SE1 overlaps the stacked film FL above the partition 6B. The edge portion E2 of the sealing layer SE1 is located directly above the partition 6B.

The sealing layer SE3 covers the sealing layer SE1. Further, the sealing layer SE3 contacts the partition 6B outward of the edge portion E2 and covers the outside of the partition 6B. This sealing layer SE3 is formed of an inorganic insulating material, for example, formed of a silicon nitride.

The resin layer RS1 is provided on the sealing layer SE1 and is filled between the partitions 6A and 6B. The edge portion E1 of the resin layer RS1 is located directly above the partition 6B and the sealing layer SE1.

The sealing layer SE2 covers the resin layer RS1. Further, the sealing layer SE2 contacts the sealing layer SE3 outward of the edge portion E1.

This configuration example can achieve the same effect as in the above configuration examples.

Even if the stacked film FL on the partition 6B is eliminated, the sealing layer SE3 blocks the cavity formed between the partition 6B and the sealing layer SE1, thereby suppressing moisture penetration to the cavity.

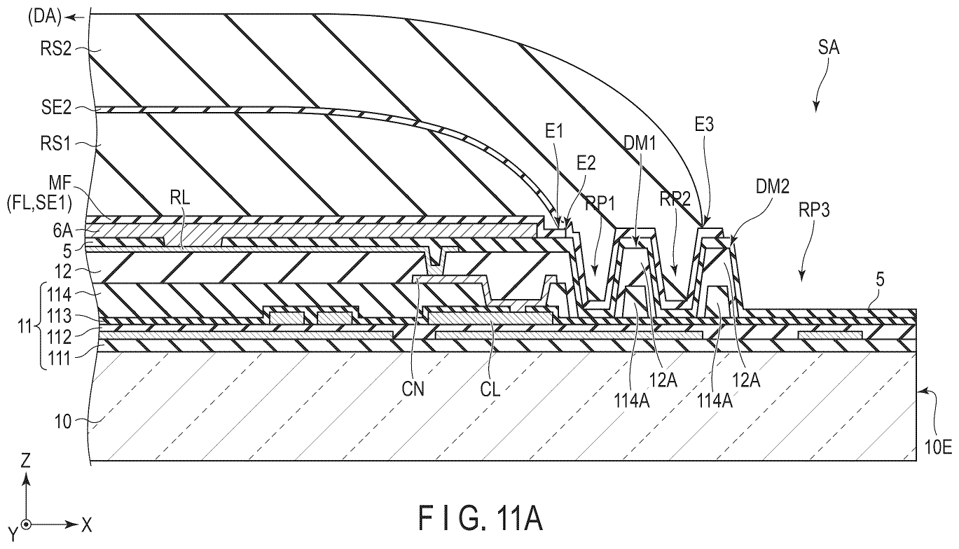

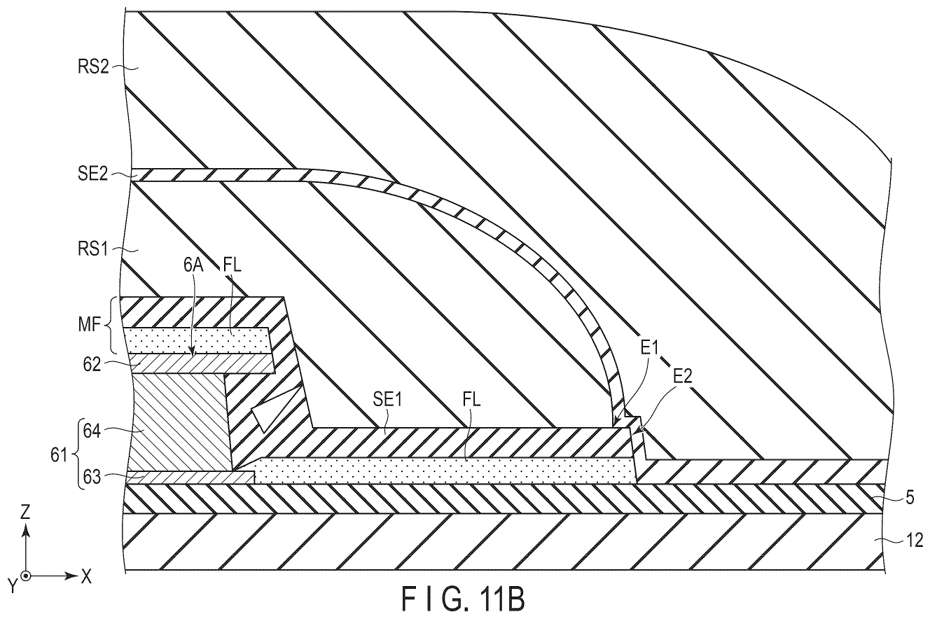

FIG. 11A is a cross-sectional view showing another configuration example of the display device DSP along the C-D line of the surrounding area SA shown in FIG. 4A.

The configuration example shown in FIG. 11A differs from the configuration example shown in FIG. 5A in that the partition 6B above the organic insulating layer 12 is not provided and that the edge portion E2 of the multilayer film MF is located between the partition 6A and the removed portion RP1. The edge portion E1 of the resin layer RS1 is located directly above the organic insulating layer 12 and the multilayer film MF. The sealing layer SE2 covers the resin layer RS1, contacts the inorganic insulating layer 5 outside the edge portion E2, and seals the resin layer RS1.

FIG. 11B is a cross-sectional view showing the vicinity of the edge portions E1 and E2 shown in FIG. 11A in an enlarged manner. FIG. 11B omits the illustration of the components below the organic insulating layer 12.

The stacked film FL is divided into a portion provided on the partition 6A and a portion provided on the inorganic insulating layer 5 outside the partition 6A.

The sealing layer SE1 covers the stacked film FL above the partition 6A and covers the partition 6A. Further, the sealing layer SE1 covers the stacked film FL outside the partition 6A. The edge portion E2 of the sealing layer SE1 is located directly above the inorganic insulating layer 5 outside the partition 6A.

The resin layer RS1 is provided on the sealing layer SE1. The edge portion E1 of the resin layer RS1 is located directly above the sealing layer SE1 outside the partition 6A.

The sealing layer SE2 covers the resin layer RS1. Further, the sealing layer SE2 contacts the sealing layer SE1 outward of the edge portion E1 and contacts the inorganic insulating layer 5 outward of the edge portion E2.

This configuration example can achieve the same effect as in the above configuration examples.

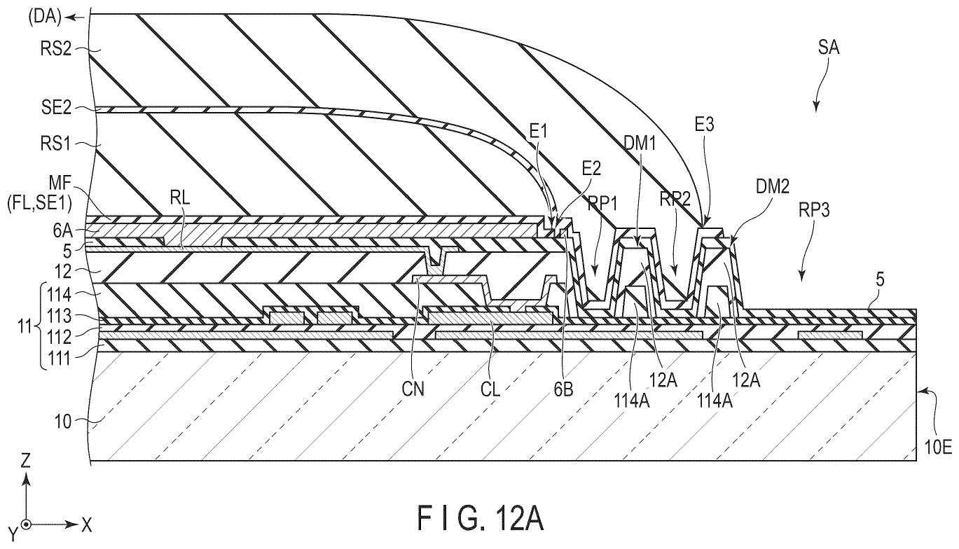

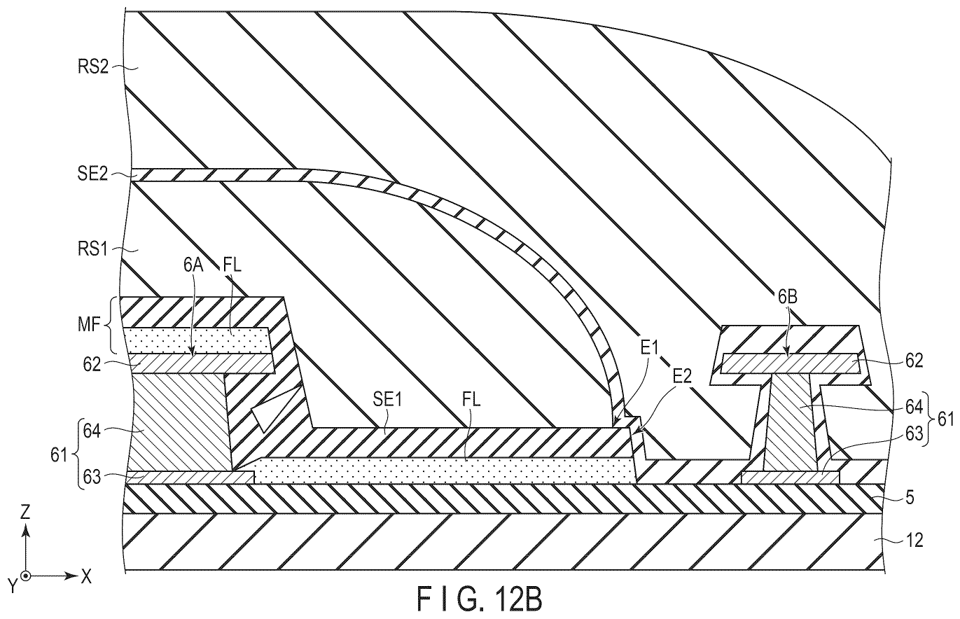

FIG. 12A is a cross-sectional view showing another configuration example of the display device DSP along the C-D line of the surrounding area SA shown in FIG. 4A.

The configuration example shown in FIG. 12A differs from the configuration example shown in FIG. 11A in that the partition 6B above the organic insulating layer 12 is provided and that the edge portion E2 of the multilayer film MF is located between the partitions 6A and 6B. The edge portion E1 of the resin layer RS1 is located directly above the organic insulating layer 12 and the multilayer film MF. The sealing layer SE2 covers the resin layer RS1, contacts the inorganic insulating layer 5 outside the edge portion E2, and seals the resin layer RS1. The sealing layer SE2 covers the partition 6B.

FIG. 12B is a cross-sectional view showing the vicinity of the edge portions E1 and E2 shown in FIG. 12A in an enlarged manner. FIG. 12B omits the illustration of the components below the organic insulating layer 12.

The stacked film FL is divided into a portion provided on the partition 6A and a portion provided on the inorganic insulating layer 5 between the partitions 6A and 6B.

The sealing layer SE1 covers the stacked film FL above the partition 6A and covers the partition 6A. Further, the sealing layer SE1 covers the stacked film FL between the partitions 6A and 6B. The edge portion E2 of the sealing layer SE1 is located directly above the inorganic insulating layer 5 between the partitions 6A and 6B.

The resin layer RS1 is provided on the sealing layer SE1. The edge portion E1 of the resin layer RS1 is located directly above the sealing layer SE1 between the partitions 6A and 6B. The partition 6B is exposed from all of the stacked film FL, the sealing layer SE1, and the resin layer RS1.

The sealing layer SE2 covers the resin layer RS1. Further, the sealing layer SE2 contacts the sealing layer SE1 outward of the edge portion E1 and contacts the inorganic insulating layer 5 outward of the edge portion E2. Further, the sealing layer SE2 covers the partition 6B.

This configuration example can achieve the same effect as in the above configuration examples.

In the embodiment, the sealing layers SE1, SE11, SE12, and SE13 correspond to the first sealing layer, the resin layer RS1 corresponds to the first resin layer, the sealing layer SE2 corresponds to the second sealing layer, the resin layer RS2 corresponds to the second resin layer, and the sealing layer SE3 corresponds to the third sealing layer. In the partition 6, the lower portion 61 corresponds to the first lower portion, and the upper portion 62 corresponds to the first upper portion. The edge portion E1 of the resin layer RS1 corresponds to the first edge portion of the first resin layer, the edge portion E2 of the sealing layer SE1 (or the edge portion of the multilayer film MF) corresponds to the second edge portion of the first sealing layer, and the edge portion E3 of the resin layer RS2 corresponds to the third edge portion of the second resin layer. The partition 6A corresponds to the first partition. The partition 6B corresponds to the second partition.

As described above, the present embodiment can provide a display device which can suppress decreases in reliability.

All of the display devices that can be implemented by a person of ordinary skill in the art through arbitrary design changes to the display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A display device comprising:
a substrate;
an organic insulating layer provided across a display area for displaying images and a surrounding area outside the display area above the substrate;
an inorganic insulating layer provided across the display area and the surrounding area and covering the organic insulating layer;
a lower electrode provided on the organic insulating layer in the display area and having a peripheral portion covered with the inorganic insulating layer;
an organic layer provided on the lower electrode and including a light emitting layer;
an upper electrode provided on the organic layer;
a partition formed in an overhang shape and comprising a first lower portion provided on the inorganic insulating layer, having conductivity, and contacting the upper electrode and a first upper portion provided on the first lower portion; and
a stacked film provided in the surrounding area and including a thin film formed of same material as each of the organic layer and the upper electrode;
a first sealing layer formed of an inorganic insulating material and provided on the stacked film; and
a first resin layer provided above the first sealing layer, wherein
a first edge portion of the first resin layer is located directly above the first sealing layer.

2. The display device of claim 1, wherein
a second edge portion of the first sealing layer is located directly above the organic insulating layer.

3. The display device of claim 2, wherein
a removed portion penetrating the organic insulating layer surrounds the display area in the surrounding area.

4. The display device of claim 3, wherein
the removed portion extends to an edge portion of the substrate.

5. The display device of claim 3, wherein
the second edge portion is located between the display area and the removed portion.

6. The display device of claim 5, further comprising:
a first partition surrounding the display area and electrically connected to the partition in the surrounding area; and
a second partition surrounding the first partition and spaced apart from the first partition, wherein
each of the first partition and the second partition is formed in an overhang shape, and
the second edge portion is located directly above the second partition.

7. The display device of claim 6, further comprising:
a second sealing layer formed of an inorganic insulating material, covering the first resin layer, and covering the second partition outside the second edge portion.

8. The display device of claim 6, wherein
the first resin layer is filled between the first partition and the second partition.

9. The display device of claim 5, further comprising:
a first partition surrounding the display area and electrically connected to the partition in the surrounding area, wherein
the first partition is formed in an overhang shape, and
the second edge portion is located between the first partition and the removed portion.

10. The display device of claim 9, further comprising:
a second sealing layer formed of an inorganic insulating material, covering the first resin layer, and contacting the inorganic insulating layer outside the second edge portion.

11. The display device of claim 9, further comprising:
a second partition spaced apart from the first partition, surrounding the first partition, and provided between the first partition and the removed portion in the surrounding area, wherein
the second partition is formed in an overhang shape, and
the second edge portion is located between the first partition and the second partition.

12. The display device of claim 11, further comprising:
a second sealing layer formed of an inorganic insulating material, covering the first resin layer, contacting the inorganic insulating layer outside the second edge portion, and covering the second partition.

13. The display device of claim 6, wherein
at least one of an outer edge of the first partition and the second partition are formed continuously without being cut, and
the outer edge faces the second partition.

14. The display device of claim 1, further comprising:
a second sealing layer formed of an inorganic insulating material and covering the first resin layer; and
a third sealing layer formed of an inorganic insulating material, provided between the first sealing layer and the first resin layer, and covering the first sealing layer, wherein
the second sealing layer contacts the third sealing layer outside the first edge portion.

15. A display device comprising:
a substrate;
an organic insulating layer provided across a display area for displaying images and a surrounding area outside the display area above the substrate;
an inorganic insulating layer provided across the display area and the surrounding area and covering the organic insulating layer;
a lower electrode provided on the organic insulating layer in the display area and having a peripheral portion covered with the inorganic insulating layer;
an organic layer provided on the lower electrode and including a light emitting layer;
an upper electrode provided on the organic layer;
a partition formed in an overhang shape and comprising a first lower portion provided on the inorganic insulating layer, having conductivity, and contacting the upper electrode and a first upper portion provided on the first lower portion;
a stacked film provided in the surrounding area and including a thin film formed of same material as each of the organic layer and the upper electrode;
a first sealing layer formed of an inorganic insulating material and provided on the stacked film;
a first resin layer provided above the first sealing layer;
a second sealing layer covering the first resin layer; and
a second resin layer provided on the second sealing layer, wherein
a third edge portion of the second resin layer is located directly above the first sealing layer.

16. The display device of claim 15, wherein
the first resin layer is not interposed between the third edge portion and the first sealing layer.

17. The display device of claim 16, further comprising:
a dam portion surrounding the display area and spaced apart from the organic insulating layer, wherein
the third edge portion is located directly above the dam portion.

18. The display device of claim 17, wherein
the removed portion penetrating the organic insulating layer extends to an edge portion of the substrate outside the dam portion.

19. The display device of claim 17, wherein
the dam portion extends to an edge portion of the substrate.

20. The display device of claim 16, wherein
the organic insulating layer is not interposed between the third edge portion and the substrate.
